(19) United States
(12) Patent Application Publication
(10) Pub. No.: US 2025/0372356 A1
(43) Pub. Date: Dec. 4, 2025

(54) PLASMA PROCESSING APPARATUS, SUBSTRATE SUPPORT, AND METHOD FOR CORRECTING WEAR OF EDGE RING

(71) Applicant: Tokyo Electron Limited, Tokyo (JP)

(72) Inventors: Akira NAGAYAMA, Miyagi (JP); Takeshi AKAO, Miyagi (JP)

(21) Appl. No.: 19/300,884

(22) Filed: Aug. 15, 2025

Related U.S. Application Data
(63) Continuation of application No. PCT/JP2024/005764, filed on Feb. 19, 2024.

(30) Foreign Application Priority Data
Feb. 28, 2023 (JP) 2023-029994

(51) Int. Cl. H01J 37/32

(52) U.S. Cl. CPC H01J 37/32642; H01J 37/32541; H01J 37/32715; H01J 37/32807; H01J 2237/2007

(57) ABSTRACT

A plasma processing apparatus includes a plasma processing chamber, a base disposed inside the plasma processing chamber, and including a first part having an upper surface on which an electrostatic chuck is disposed, and a second part surrounding a periphery of the first part and having an upper surface higher than the first part, and an edge ring formed by film formation on the upper surface of the second part and on a portion of side surfaces of the second part.

### CROSS-REFERENCE TO RELATED APPLICATIONS

This application is a continuation application of International Application No. PCT/JP2024/005764 filed on Feb. 19, 2024 and designated the U.S., which is based upon and claims priority to Japanese Patent Application No. 2023-029994, filed on Feb. 28, 2023, the entire contents of which are incorporated herein by reference.

### BACKGROUND

### 1. Field of the Invention

The present disclosure relates to plasma processing apparatuses, substrate supports, and methods for correcting wear of edge rings.

### 2. Description of the Related Art

For example, Japanese Laid-Open Patent Publication No. 2019-21707 proposes a substrate processing apparatus provided with a thermal interface sheet is provided between a stage and a focus ring (edge ring). For example, Japanese Laid-Open Patent Publication No. 2019-216176 proposes a substrate processing apparatus that supplies a heat transfer gas between an electrostatic chuck and the focus ring.

### SUMMARY

One aspect of the present disclosure provides a plasma processing apparatus having an edge ring with reduced thermal resistance and improved thermal conductivity, a substrate support, and a method for correcting wear of the edge ring.

According to one aspect of the present disclosure, a plasma processing apparatus includes a plasma processing chamber; a base disposed inside the plasma processing chamber, and including a first part having an upper surface on which an electrostatic chuck is disposed, and a second part surrounding a periphery of the first part and having an upper surface higher than the first part; and an edge ring formed by film formation on the upper surface of the second part and on a portion of side surfaces of the second part.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a diagram illustrating an example of a plasma processing system according to one embodiment;

FIG. 2A is a longitudinal cross sectional view schematically illustrating an example of a substrate support having an edge ring of a reference example 1;

FIG. 2B is a longitudinal cross sectional view schematically illustrating an example of a substrate support having an edge ring of a reference example 2;

FIG. 2C is a transverse cross sectional view schematically illustrating an example of a substrate support having an edge ring according to one embodiment;

FIG. 2D is a diagram illustrating examples of temperatures of the edge ring and a substrate of the reference examples 1 and 2;

FIG. 2E is a diagram illustrating examples of temperatures of the edge ring and a substrate according to one embodiment;

FIG. 3 is a diagram illustrating an edge ring, an electrode layer, and a power feeding structure according to a first embodiment;

FIG. 4 is a diagram illustrating the edge ring, the electrode layer, and the power feeding structure according to a second embodiment;

FIG. 5A is a longitudinal cross sectional view schematically illustrating an example of the substrate support according to a modification;

FIG. 5B is a longitudinal cross sectional view schematically illustrating an example of the substrate support according to a modification;

FIG. 5C is a longitudinal cross sectional view schematically illustrating an example of the substrate support according to a modification;

FIG. 6 is a transverse cross sectional view schematically illustrating an example of a flow path in a substrate support illustrated in FIG. 5A through FIG. 5C; and

FIG. 7 is a flow chart illustrating an example of a method for correcting wear of the edge ring according to one embodiment.

### DETAILED DESCRIPTION

Hereinafter, embodiments of the present disclosure will be described with reference to the drawings. In the drawings, the same constituent elements are designated by the same reference numerals, and a redundant description thereof may be omitted.

### [Plasma Processing System]

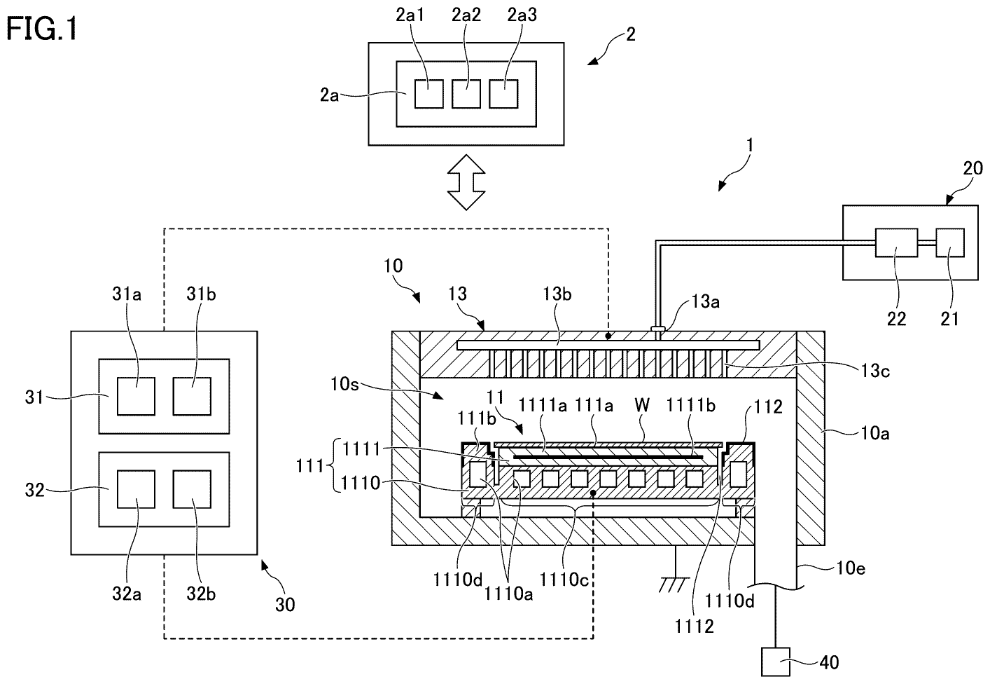

Hereinafter, a configuration example of a plasma processing system will be described. FIG. 1 is a diagram for explaining the configuration example of a capacitively coupled plasma processing apparatus.

The plasma processing system includes a capacitively coupled plasma processing apparatus 1 and a control device 2. The capacitively coupled plasma processing apparatus 1 includes a plasma processing chamber 10, a gas supply 20, a power supply 30, and an exhaust system 40. The plasma processing apparatus 1 also includes a substrate support 11 and a gas inlet section. The gas inlet section is configured to introduce at least one process gas into the plasma processing chamber 10. The gas inlet section includes a shower head 13. The substrate support 11 is disposed inside the plasma processing chamber 10. The shower head 13 is disposed above the substrate support 11. In one embodiment, the shower head 13 constitutes at least a portion of a ceiling of the plasma processing chamber 10. The plasma processing chamber 10 includes a plasma processing space 10s defined by the shower head 13, a sidewall 10a of the plasma processing chamber 10, and the substrate support 11. The plasma processing chamber 10 has at least one gas inlet for supplying at least one process gas to the plasma processing space 10s, and at least one gas outlet for discharging the gas from the plasma processing space 10s. The plasma processing chamber 10 is grounded. The shower head 13 and the substrate support 11 are electrically insulated from a housing of the plasma processing chamber 10.

The substrate support 11 includes a ring assembly having a main body 111 and an edge ring 112. The main body 111 includes a central region 111a for supporting a substrate W, and an annular region 111b for supporting the ring assembly. A wafer is an example of the substrate W. The annular region 111b of the main body 111 surrounds the central region 111a of the main body 111 in a plan view. The substrate W is disposed on the central region 111a of the main body 111, and the ring assembly is disposed on the annular region 111b of the main body 111 to surround the substrate W on the central region 111a of the main body 111, and particularly, the edge ring 112 of the ring assembly is formed on the annular region 111b by film formation (for example, thermal spraying). Accordingly, the central region 111a is also referred to as a substrate support surface for supporting the substrate W, and the annular region 111b is also referred to as a ring support surface for supporting the ring assembly.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed inside the ceramic member 1111a. The ceramic member 1111a includes the central region 111a. In one embodiment, the ceramic member 1111a also includes the annular region 111b. Other members surrounding the electrostatic chuck 1111, such as an annular electrostatic chuck or an annular insulating member, may include the annular region 111b. In this case, the ring assembly may be disposed on the annular electrostatic chuck or the annular insulating member, or may be disposed on both the electrostatic chuck 1111 and the annular insulating member. In addition, at least one RF/DC electrode coupled to a radio frequency (RF) power supply 31 and/or a direct current (DC) power supply 32 which will be described later, may be disposed inside the ceramic member 1111a. In this case, at least one RF/DC electrode functions as a lower electrode. In a case where a bias RF signal and/or a DC signal which will be described later are supplied to at least one RF/DC electrode, the RF/DC electrode may also be referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly includes one or more annular members. In one embodiment, the one or more annular members include the edge ring 112 and at least one cover ring. The edge ring 112 is formed of a conductive material or an insulating material, and the cover ring is formed of an insulating material.

Moreover, the substrate support 11 may include a temperature control module configured to control at least one of the electrostatic chuck 1111, the ring assembly, and the substrate W to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed inside the ceramic member 1111a of the electrostatic chuck 1111. Further, the substrate support 11 may include a heat transfer gas supply configured to supply a heat transfer gas to a gap between a back surface of the substrate W and the central region 111a.

The shower head 13 is configured to introduce at least one process gas from the gas supply 20 into the plasma processing space 10s. The shower head 13 includes at least one gas inlet port 13a, at least one gas diffusion chamber 13b, and a plurality of gas discharge ports 13c. The process gas supplied to the gas inlet port 13a passes through the gas diffusion chamber 13b, and is introduced into the plasma processing space 10s from the plurality of gas discharge ports 13c. The shower head 13 also includes at least one upper electrode. The gas inlet section may include, in addition to the shower head 13, one or more side gas injectors (SGIs) attached to one or more openings formed in the sidewall 10a.

The gas supply 20 may include at least one gas source 21 and at least one flow rate controller 22. In one embodiment, the gas supply 20 is configured to supply at least one process gas from each corresponding gas source 21 to the shower head 13 via each corresponding flow rate controller 22. Each flow rate controller 22 may include a mass flow controller or a pressure-controlled flow rate controller, for example. In addition, the gas supply 20 may include one or more flow rate modulation devices configured to modulate or pulse the flow rate of the at least one process gas.

The power supply 30 includes an RF power supply 31 coupled to the plasma processing chamber 10 via at least one impedance matching circuit. The RF power supply 31 is configured to supply at least one RF signal (RF power) to the at least one lower electrode and/or the at least one upper electrode. Accordingly, plasma is formed from the at least one process gas supplied to the plasma processing space 10s. Hence, the RF power supply 31 may function as at least a part of a plasma generation section configured to generate the plasma from one or more process gases inside the plasma processing chamber 10. Moreover, by supplying the bias RF signal to the at least one lower electrode, a bias potential is generated in the substrate W, and ion components in the formed plasma can be attracted to the substrate W.

In one embodiment, the RF power supply 31 includes a first RF generator 31a and a second RF generator 31b. The first RF generator 31a is coupled to the at least one lower electrode and/or the at least one upper electrode via at least one impedance matching circuit, and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The generated one or more source RF signals are supplied to the at least one lower electrode and/or the at least one upper electrode.

The second RF generator 31b is coupled to the at least one lower electrode via at least one impedance matching circuit, and is configured to generate a bias RF signal (bias RF power). The frequency of the bias RF signal may be the same as or may be different from the frequency of the source RF signal. In one embodiment, the bias RF signal has a frequency that is lower than the frequency of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or more bias RF signals are supplied to the at least one lower electrode. In addition, in various embodiments, at least one of the source RF signal and the bias RF signal may be pulsed.

The power supply 30 may also include a DC power supply 32 coupled to the plasma processing chamber 10. The DC power supply 32 includes a first DC generator 32a and a second DC generator 32b. In one embodiment, the first DC generator 32a is connected to the at least one lower electrode, and is configured to generate a first DC signal. The generated first DC signal is applied to the at least one lower electrode. In one embodiment, the second DC generator 32b is connected to the at least one upper electrode, and is configured to generate a second DC signal. The generated second DC signal is applied to the at least one upper electrode.

In various embodiments, at least one of the first and second DC signals may be pulsed. In this case, a sequence of voltage pulses is applied to the at least one lower electrode and/or the at least one upper electrode. The voltage pulse may have a pulse waveform having a rectangular shape, a trapezoidal shape, a triangular shape, or a combination thereof. In one embodiment, a waveform generator for generating a sequence of voltage pulses from a DC signal is connected between the first DC generator 32a and the at least one lower electrode. Accordingly, the first DC generator 32a and the waveform generator constitute a voltage pulse generator. In a case where the second DC generator 32b and the waveform generator constitute a voltage pulse generator, the voltage pulse generator is connected to the at least one upper electrode. The voltage pulse may have a positive polarity or a negative polarity. Moreover, the sequence of voltage pulses may include one or more positive voltage pulses and one or more negative voltage pulses in one cycle. The first and second DC generators 32a and 32b may be provided in addition to the RF power supply 31, or the first DC generator 32a may be provided in place of the second RF generator 31b.

The exhaust system 40 may be connected to a gas outlet 10e provided at a bottom of the plasma processing chamber 10, for example. The exhaust system 40 may include a pressure regulating valve and a vacuum pump. A pressure inside the plasma processing space 10s is adjusted by the pressure regulating valve. The vacuum pump may include a turbomolecular pump, a dry pump, or a combination thereof.

The control device 2 processes instructions that are executable by a computer and cause the plasma processing apparatus 1 to perform various processes described in the present disclosure. The control device 2 may be configured to control various parts of the plasma processing apparatus 1 to perform the various processes described herein. In one embodiment, a part or all of the control device 2 may be included in the plasma processing apparatus 1. The control device 2 may be control circuitry including a processing device 2a1, a storage device 2a2, and a communication interface 2a3. The control device 2 is implemented by a computer 2a, for example. The processing device 2al may be configured to read a program from the storage device 2a2 and execute the read program to perform various control operations. The program may be stored in the storage device 2a2 in advance, or may be acquired via a medium when necessary. The acquired program is stored in the storage device 2a2, and the program is read from the storage device 2al and executed by the processing device 2a2. The medium may be various storage media readable by the computer 2a, or may be a communication line connected to the communication interface 2a3. The processing device 2al may be a central processing unit (CPU). The storage device 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line, such as a local area network (LAN) or the like.

### [Base]

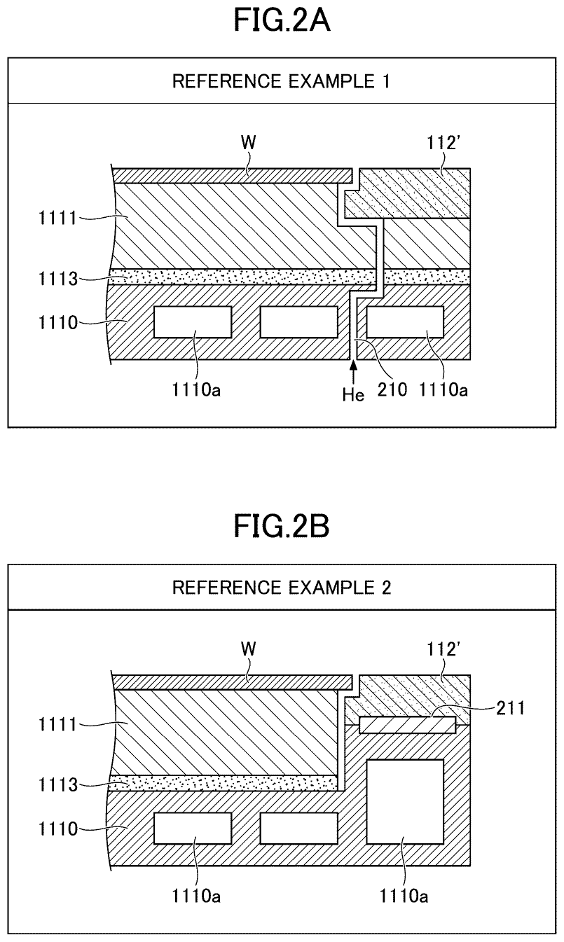

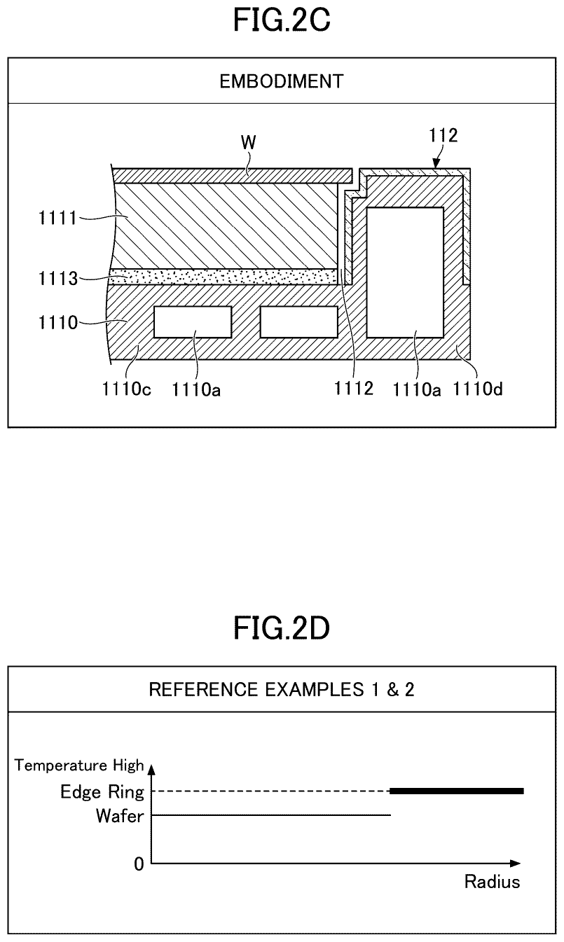

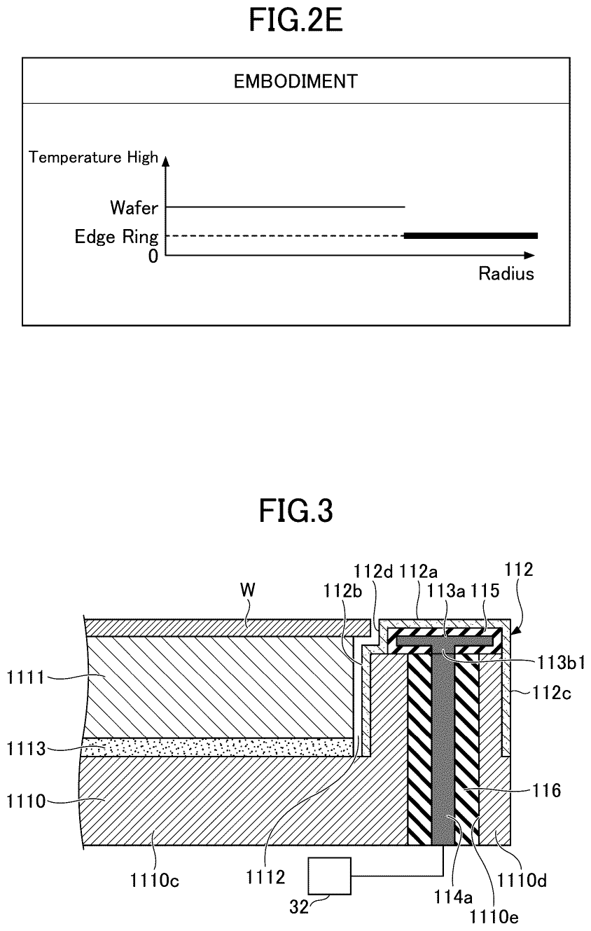

The base 1110 is disposed inside the plasma processing chamber 10, and includes a first part 1110c on which the electrostatic chuck 1111 is disposed and a second part 1110d surrounding a periphery of the first part 1110c. The first part 1110c is a portion of the base 1110 of the main body 111 corresponding to the central region 111a for supporting the substrate W. The electrostatic chuck 1111 is bonded to an upper surface of the first part 1110c via an adhesive 1113 (refer to FIG. 2C, FIG. 3, or the like). The second part 1110d is a portion of the base 1110 of the main body 111 corresponding to the annular region 111b for supporting the edge ring 112 (ring assembly). An upper surface of the second part 1110d is higher than the upper surface of the first part 1110c.

### [Edge Ring]

The edge ring 112 is formed on the upper surface of the second part 1110d and portions of side surfaces of the second part 1110d by film formation (for example, thermal spraying). The portions of the side surfaces of the second part 1110d on which the edge ring 112 is formed by the film formation is a portion of an inner side surface and a portion of an outer side surface of the second part 1110d that are continuous with the upper surface of the second part 1110d. A gap 1112 is provided between the electrostatic chuck 1111 provided on the upper surface of the first part 1110c and the second part 1110d. The first part 1110c and the second part 1110d are integrated at a bottom of the base 1110. The flow path 1110a formed in the first part 1110c and the second part 1110d is integrated, and has a spiral shape, for example. However, the shape of the flow path 1110a is not limited thereto, and may be a radial shape or the like. A thermal control medium circulates through the flow path 1110a formed in the first part 1110c and the second part 1110d, to cool the substrate W and the edge ring 112.

A configuration of the edge ring 112 according to one embodiment will be described in comparison with a configuration of an edge ring 112′ of reference examples, with reference to FIG. 2A through FIG. 2E. FIG. 2A and FIG. 2B are longitudinal cross sectional views schematically illustrating examples of a substrate support having the edge ring 112′ of the reference examples, and FIG. 2C is a transverse cross sectional view schematically illustrating an example of the substrate support having the edge ring 112 according to one embodiment. FIG. 2D is a diagram illustrating examples of temperatures of the edge ring 112′ and the substrate W of the reference examples 1 and 2. FIG. 2E is a diagram illustrating examples of temperatures of the edge ring 112 and the substrate W according to one embodiment.

As the RF power used when performing the plasma processing on the substrate W increases, heat input from the plasma to the edge ring is also increasing. For this reason, there are increasing demands to further improve a temperature controllability of the edge ring, and a heat dissipation technology for the edge ring is becoming increasingly important due to the heat input.

For example, in the substrate support having the edge ring 112′ of reference example 1 illustrated in FIG. 2A, the edge ring 112′ is attracted to the electrostatic chuck 1111 by supplying a DC voltage to the electrostatic electrode (not illustrated) of the electrostatic chuck 1111 below the edge ring 112′. Moreover, a helium (He) gas, which is an example of the heat transfer gas, is filled between a back surface of the edge ring 112′ and an edge ring support surface of the electrostatic chuck 1111 from a heat transfer gas line 210, thereby dissipating the heat input to the edge ring 112′. However, in a case where heat conduction between the adhesive 1113 and the heat transfer gas between the base 1110 and the electrostatic chuck 1111 is insufficient, the thermal resistance increases. Accordingly, in the configuration illustrated in FIG. 2A, the temperature of the edge ring 112′ becomes higher than the temperature of the substrate (wafer), as illustrated in FIG. 2D.

In the substrate support having the edge ring 112′ of reference example 2 illustrated in FIG. 2B, the edge ring 112′ is attached to the base 1110 using the heat transfer sheet 211, thereby dissipating the heat input to the edge ring 112′. However, in a case where heat conduction of the heat transfer sheet 211 is insufficient, the thermal resistance increases. Accordingly, in the configuration illustrated in FIG. 2B, the temperature of the edge ring 112′ becomes higher than the temperature of the substrate (wafer), as illustrated in FIG. 2D.

In contrast, the edge ring 112 according to one embodiment illustrated in FIG. 2C is formed on the second part 1110d of the base 1110 using the film formation (for example, thermal spraying). Accordingly, the thermal resistance can be reduced and the edge ring 112 having a high thermal conductivity can be provided, when compared to the configurations illustrated in FIG. 2A and FIG. 2B in which the thermal resistance of the adhesive 1113, the heat transfer gas, the heat transfer sheet, or the like is high.

Accordingly, a thin edge ring 112 can be formed, an adhesive or the like is not required, and the height of the base 1110 of the second part 1110d can be increased to the height of the substrate W. Hence, the height of the flow path 1110a of the second part 1110d can be made higher than the height of the flow path 1110a of the first part 1110c, and the flow path 1110a of the second part 1110d can be positioned closer to the plasma. For this reason, when the thermal control medium flows through the flow path 1110a, a heat dissipation performance of the edge ring 112 can be improved compared to those of the reference examples 1 and 2 illustrated in FIG. 2A and FIG. 2B. Accordingly, in one embodiment illustrated in FIG. 2C, the temperature of the edge ring 112 becomes lower than the temperature of the substrate (wafer), as illustrated in FIG. 2E, and it is possible to further lower the temperature of the edge ring 112.

A material with low particle generation due to reduced wear when the edge ring 112 is exposed to the plasma is selected as a film forming material (thermal spraying material) for the edge ring 112. The film forming material (thermal spraying material) for the edge ring 112 having a plasma resistance may be silicon (Si) which is the same as the material used for the substrate W, or may be silicon carbide (SiC) or tungsten carbide (WC). These materials are suitably used for the material forming the edge ring 112 by the film formation (for example, thermal spraying), because these materials exhibit low wear and low particle generation when exposed to the plasma.

The edge ring 112 may be formed by film formation (for example, thermal spraying) on the base 1110 that is subjected to an anodic oxidation treatment (alumite treatment) for insulation. The edge ring 112 may be formed by film formation (for example, thermal spraying) on the base 1110 that is formed with an insulating material by film formation (for example, thermal spraying).

### [Electrode and Power Feeding Structure]

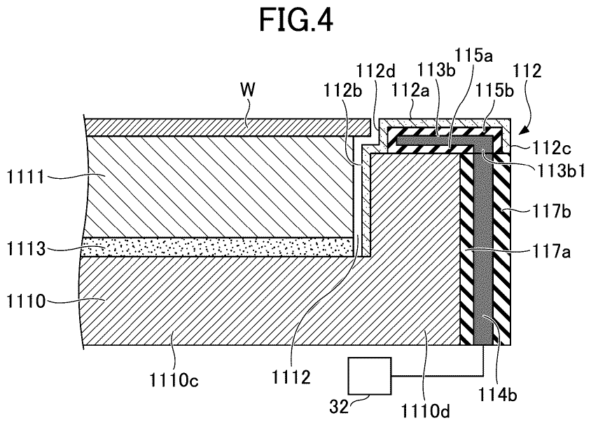

The edge ring 112, the electrode, and a power feeding structure disposed on the second part 1110d of the base 1110 according to one embodiment illustrated in FIG. 2C will be described with reference to FIG. 3 and FIG. 4.

### First Embodiment

FIG. 3 is a diagram illustrating the edge ring 112, the electrode, and the power feeding structure according to a first embodiment. In the following description, a case where the edge ring 112 is formed by thermal spraying will be described as an example. In the first embodiment, the edge ring 112 has an upper surface portion 112a that is formed on the upper surface of the second part 1110d of the base 1110 in an annular shape by thermal spraying. Further, the edge ring 112 has a step portion 112d formed on a stepped section of the inner side surface continuous with the upper surface by thermal spraying, an inner side surface portion 112b formed from the step portion 112d to a height of a bottom of the gap 1112 by thermal spraying, and an outer side surface portion 112c formed on the outer side surface continuous with the upper surface by thermal spraying. The inner side surface portion 112b and the outer side surface portion 112c are formed to the same height by the thermal spraying, but are not limited thereto, and may be formed to different heights by the thermal spraying. The upper surface portion 112a of the edge ring 112 and some of the side surface portions of the edge ring 112 are surfaces that are easily exposed to the plasma. In the example illustrated in FIG. 3, some of the side surface portions of the edge ring 112 include the inner side surface portion 112b, the outer side surface portion 112c, and the step portion 112d.

The upper surface portion 112a of the edge ring 112 and some of the side surface portions of the edge ring 112 may be formed of the same thermal spraying material that is Si, SiC or WC, or may be formed of different thermal spraying materials. For example, the upper surface portion 112a of the edge ring 112 may be formed of SiC, Si or WC, and the inner side surface portion 112b, the outer side surface portion 112c, and the step portion 112d may be formed of SiC, Si or WC but other than the material used for the upper surface portion 112a. The upper surface portion 112a, the outer side surface portion 112c, the inner side surface portion 112b, and the step portion 112d may be formed of different materials.

The edge ring 112 may be formed by thermal spraying only the upper surface portion 112a, and the thermal spraying does not need to be performed on the side surfaces. However, because particles may be generated from portions of the side surfaces of the base 1110 exposed to the plasma, the edge ring 112 is preferably formed by thermal spraying not only on the upper surface of the second part 1110d but also on the side surfaces thereof.

In the first embodiment illustrated in FIG. 3, the upper surface portion 112a of the edge ring 112 is formed on the upper surface of the second part 1110d via an electrode layer 113a covered with the first insulator 115. The first insulator 115 is formed by thermal spraying or a structure (bulk), and the electrode layer 113a is embedded in the first insulator 115. The first insulator 115 may be a sheet. A material used for the first insulator 115 may be alumina or yttria.

The electrode layer 113a may be connected to a power supply terminal 114a penetrating the second part 1110d. In this case, a cylindrical insulator 116 formed of a ceramic member may be inserted into a through hole 1110e formed in the second part 1110d, and the power supply terminal 114a may penetrate the insulator 116 and connect to the electrode layer 113a, thereby supplying the power from the DC power supply 32 to the electrode layer 113a. The power supply terminal 114a is connected to the electrode layer 113a by a contact portion 113b1 exposed downward from the first insulator 115.

The electrode layer 113a is formed in an annular shape, and is formed concentrically with the upper surface portion 112a of the annular edge ring 112. In the first embodiment, the power supply terminal 114a and the electrode layer 113a are formed of conductive structures. The materials used for the power supply terminal 114a and the electrode layer 113a may be the same or may be different.

The power supply terminal 114a is formed in a rod shape (linear shape) in a thickness direction from the upper surface to the lower surface of the second part 1110d, and a plurality of the power supply terminals 114a is provided in the circumferential direction. Accordingly, the contact portions 113b1 of the electrode layer 113a are formed so as to be exposed in the circumferential direction in correspondence with the power supply terminals 114a.

When manufacturing the edge ring 112 of the first embodiment, the thermal spraying of the step portion 112d and inner side surface portion 112b is performed before the electrostatic chuck 1111 is bonded onto the base 1110 using the adhesive 1113 because the gap 1112 is narrow. The thermal spraying of the upper surface portion 112a and the outer side surface portion 112c may be performed before or after the electrostatic chuck 1111 is bonded onto the base 1110. The thermal spraying of the upper surface portion 112a and the outer side surface portion 112c is performed after disposing the electrode layer 113a embedded in the first insulator 115.

### Second Embodiment

FIG. 4 is a diagram illustrating the edge ring 112, the electrode, and the power feeding structure according to a second embodiment. In the following description, a case where the edge ring 112 is formed by thermal spraying will be described as an example. In the second embodiment, the edge ring 112 has an annular upper surface portion 112a, a step portion 112d and an inner side surface portion 112b that are formed on the stepped section and an inner side surface continuous with the upper surface of the second part 1110d by thermal spraying, and an outer side surface portion 112c that is formed on an outer side surface continuous with the upper surface by thermal spraying. In the second embodiment, the inner side surface portion 112b and the outer side surface portion 112c are formed to different heights of the side surface of the second part 1110d by thermal spraying. The outer side surface portion 112c is formed to a height of the step portion 112d by thermal spraying, and the inner side surface portion 112b is formed to a height of the bottom of the gap 1112.

A thermal sprayed power supply electrode film 114b, embedded in thermal sprayed second insulating films 117a and 117b, is formed on the outer side surface of the second part 1110d, and the power supply electrode film 114b is connected to an electrode film 113b. The electrode layer 113a and the electrode film 113b are also collectively referred to as an electrode layer 113.

In the second embodiment, all of the electrodes and the power feeding structures are formed by thermal spraying. That is, first insulating films 115a and 115b, the electrode film 113b, the power supply electrode film 114b, and the second insulating films 117a and 117b are formed by thermal spraying.

When manufacturing the edge ring 112 of the second embodiment, the thermal spraying of the step portion 112d and the inner side surface portion 112b is performed before the electrostatic chuck 1111 is bonded onto the base 1110 using the adhesive 1113. The thermal spraying of the upper surface portion 112a and the outer side surface portion 112c may be performed before or after the electrostatic chuck 1111 is bonded onto the base 1110. The thermal spraying of the upper surface portion 112a and the outer side surface portion 112c is performed after thermal spraying of the power supply electrode film 114b, the electrode film 113b and a periphery thereof.

When manufacturing the power supply electrode film 114b and a periphery thereof, the second insulating film 117a is first formed on the outer side surface of the second part 1110d by thermal spraying. After the second insulating film 117a is formed by thermal spraying, the power supply electrode film 114b is formed by thermal spraying, and the second insulating film 117b is formed by thermal spraying. The second insulating films 117a and 117b may be formed of alumina or yttria. The power supply electrode film 114b is formed by thermal spraying of a metal thermal spraying material, such as aluminum or the like, so as to be embedded in the second insulating films 117a and 117b formed by thermal spraying. The second insulating films 117a and 117b are examples of a second insulator.

When manufacturing the electrode film 113b and the periphery thereof, after the power supply electrode film 114b and the periphery thereof are formed by thermal spraying, the first insulating film 115a is first formed on the upper surface of the second part 1110d and the electrode film 113b and the periphery thereof by thermal spraying. After the first insulating film 115a is formed by thermal spraying, the electrode film 113b is formed by thermal spraying, and the first insulating film 115b is formed by thermal spraying. The electrode film 113b is formed in an annular shape in the circumferential direction by thermal spraying.

The electrode film 113b is formed by thermal spraying of a metal thermal spraying material, such as aluminum or the like, so as to be embedded in the first insulating films 115a and 115b formed by thermal spraying. The first insulating films 115a and 115b are examples of a first insulator. A portion of the electrode film 113b is formed to have the contact portion 113b1 exposed downward from the first insulating film 115a below the electrode film 113b. The power supply electrode film 114b is connected to the electrode film 113b by the contact portion 113b1. The materials used for the first insulating film 115a and the second insulating films 117a and 117b may be the same or may be different. In the second embodiment, because the second insulating film 117b is exposed to the plasma space, it is preferable to use an insulating material with a low particle generation and having a plasma resistance, such as alumina yttria, or the like.

The power supply electrode film 114b is formed in a rod shape (linear shape) in the thickness direction from the upper surface to the lower surface of the second part 1110d, and a plurality of the power supply electrode films 114b is provided in the circumferential direction. Accordingly, the contact portion 113b1 of the electrode film 113b is formed by thermal spraying so as to be exposed at a plurality of positions in the circumferential direction in correspondence with the plurality of power supply electrode films 114b. However, the power supply electrode film 114b may be formed over the entire circumference in the thickness direction from the upper surface to the lower surface of the second part 1110d.

The method for manufacturing the electrodes and the power feeding structures of the second embodiment is not limited to the method described above. For example, the first insulating film 115a and the second insulating film 117a may be formed integrally on the upper surface and the outer periphery of the second part 1110d. The electrode film 113b and the power supply electrode film 114b may further be formed integrally, the first insulating film 115b and the second insulating film 117b may be integrally formed thereon, and the edge ring 112 may further be formed.

The electrodes of the first embodiment and the electrodes of the second embodiment may be combined to form a hybrid structure in which a plurality of electrodes are formed on the second part 1110d. In addition, the thickness of the edge ring 112 and other films that are thermally sprayed in the first and second embodiments is 10 μm to 5 mm. A lower limit of the thickness of the film formed by thermal spraying is determined from manufacturing constraints, and an upper limit of the thickness is determined from a viewpoint of preventing cracking of the film formed by thermal spraying.

The DC voltage from the DC power supply 32 may be applied to the electrode layer 113a and the electrode film 113b for control or the like of a plasma sheath on the edge ring 112. In addition, the DC voltage from the DC power supply 32 may be pulsed and applied to the electrode layer 113a and the electrode film 113b in order to improve an etched shape by controlling the plasma. The electrode layer 113a and the electrode film 113b may be used as heater electrodes for controlling the temperature of the edge ring 112, or electrodes for controlling a potential of the edge ring 112. The RF power supply 31 illustrated in FIG. 1 may be coupled to the electrode layer 113a and the electrode film 113b to supply the RF signal (RF power) to the electrode layer 113a and the electrode film 113b. In one example, the second RF generator 31b of the RF power supply 31 is coupled to the electrode layer 113a and the electrode film 113b to supply the bias RF signal (bias RF power) to the electrode layer 113a and the electrode film 113b, for example.

### [Substrate Support According to Modification]

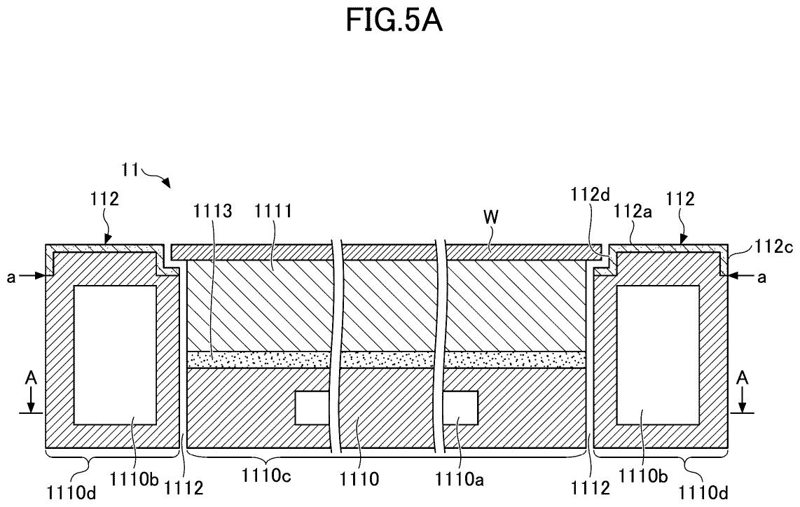

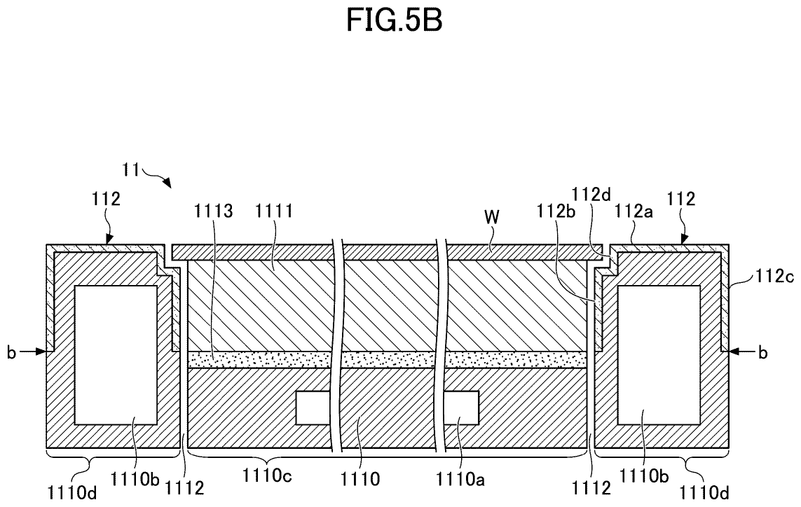

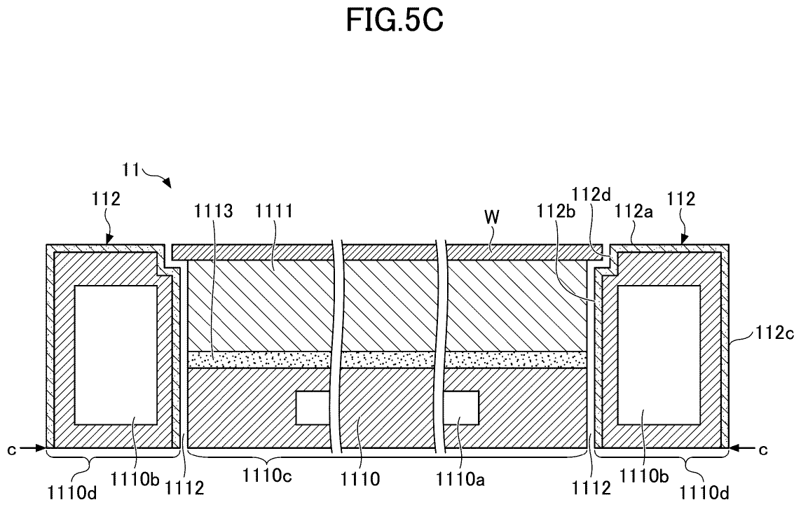

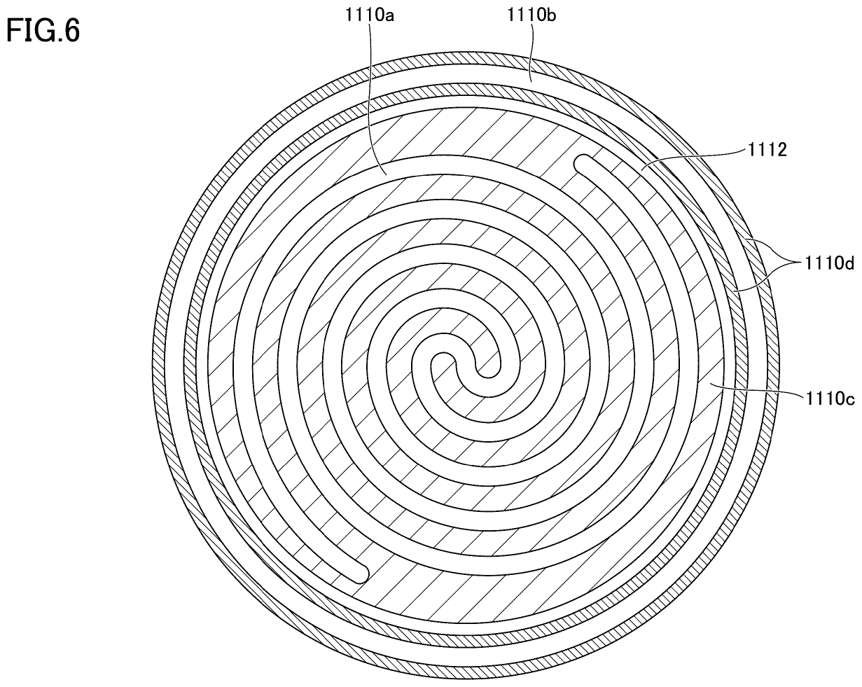

Next, the substrate support 11 according to a modification will be described with reference to FIG. 5A through FIG. 5C and FIG. 6. FIG. 5A through FIG. 5C are longitudinal cross sectional views schematically illustrating an example of the substrate support 11 according to the modification. FIG. 6 is a transverse cross sectional view schematically illustrating an example of a flow path in the substrate support 11 illustrated in FIG. 5A through FIG. 5C.

In the substrate support 11 illustrated in FIG. 1, the flow path 1110a formed in the first part 1110c and the flow path 1110a formed in the second part 1110d are integrated. In contrast, in the substrate support 11 illustrated in FIG. 5A through FIG. 5C, the first part 1110c and the second part 1110d of the base 1110 are separate entities, and the gap 1112 is provided between the first part 1110c and the second part 1110d. The first part 1110c and the second part 1110d are supported by a base support (not illustrated) that supports the base 1110.

Accordingly, in the substrate support 11 illustrated in FIG. 5A through FIG. 5C, the flow path 1110a formed in the first part 1110c and a flow path 1110b formed in the second part 1110d are separate entities.

FIG. 6 illustrates an example of the transverse cross section of the base 1110 cut along a plane A-A in FIG. 5A. An annular gap 1112 is formed between the first part 1110c and the second part 1110d. A spiral flow path 1110a is formed in the first part 1110c on an inner side of the gap 1112, and the annular flow path 1110b is formed in the second part 1110d on an outer side of the gap 1112. Because the flow path 1110a and the flow path 1110b are separate flow paths, it is possible to separately and independently control the temperature of the first part 1110c and the second part 1110d.

In the substrate support 11 illustrated in FIG. 5A, the edge ring 112 is formed (for example, by thermal spraying) on the inner side surface and the outer side surface of the side surfaces of the second part 1110d, from the upper surface of the second part 1110d to a height a illustrated at FIG. 5A, that is, to a height of the stepped section. The edge ring 112 illustrated in FIG. 5A is constituted by the upper surface portion 112a, the step portion 112d, and the outer side surface portion 112c.

In the substrate support 11 illustrated in FIG. 5B, the edge ring 112 is formed (for example, by thermal spraying) on the inner side surface and the outer side surface of the side surfaces of the second part 1110d, from the upper surface of the second part 1110d to a height b illustrated in FIG. 5B, that is, to an approximate mid-height of the second part 1110d. The edge ring 112 illustrated in FIG. 5B is constituted by the upper surface portion 112a, the step portion 112d, the inner side surface portion 112b, and the outer side surface portion 112c, and the inner side surface portion 112b and the outer side surface portion 112c cover portions of the inner side surface and the outer side surface of the second part 1110d.

In the substrate support 11 illustrated in FIG. 5C, the edge ring 112 is formed (for example, by thermal spraying) on the inner side surface and the outer side surface of the side surfaces of the second part 1110d, from the upper surface of the second part 1110d to a height c illustrated at FIG. 5C, that is, to a height of a bottom portion of the second part 1110d. The edge ring 112 illustrated in FIG. 5C is constituted by the upper surface portion 112a, the step portion 112d, the inner side surface portion 112b, and the outer side surface portion 112c, and the inner side surface portion 112b and the outer side surface portion 112c cover the entirety of the inner side surface and the outer side surface of the second part 1110d.

As described above, the side surface of the edge ring 112 is formed by film formation (for example, thermal spraying) to any height between the stepped section formed on the inner side surface of the second part 1110d and the bottom portion of the second part 1110d. After the edge ring 112 is formed by film formation (for example, thermal spraying), the electrostatic chuck 1111 is disposed on the upper surface of the first part 1110c.

### [Edge Ring Wear Correction Method]

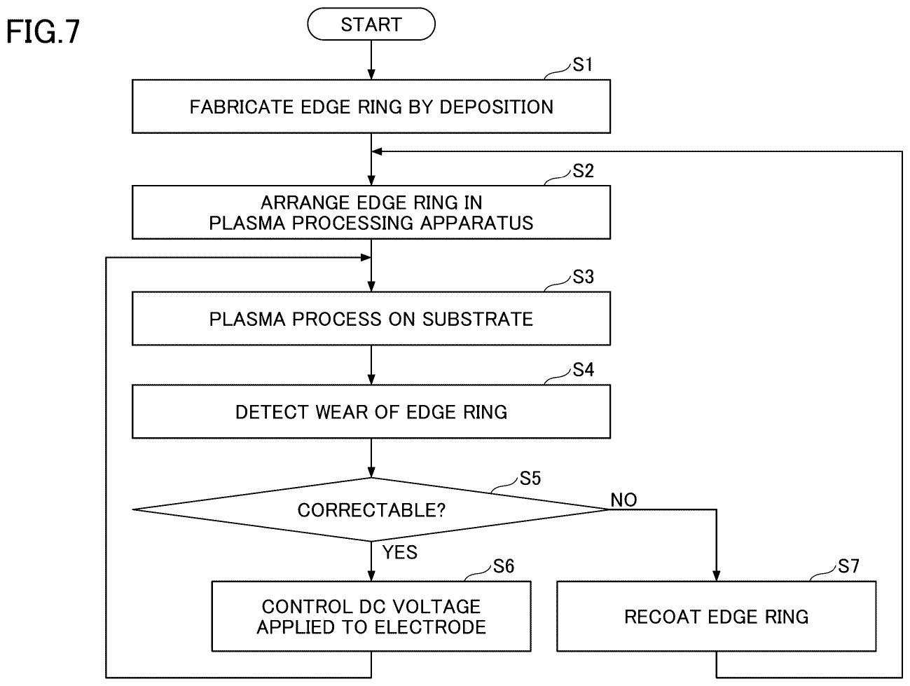

A method for using the edge ring 112 used in the plasma processing apparatus 1 will be described with reference to FIG. 7. FIG. 7 is a flow chart illustrating an example of a method for using the edge ring 112 according to one embodiment.

As described above, in the method for using the edge ring 112 illustrated in FIG. 7, first, in step S1, the edge ring 112 is manufactured by forming a film (for example, by thermal spraying) on the upper surface of the second part 1110d and portions of the side surfaces of the second part 1110d by film formation (for example, thermal spraying). Next, in step S2, the substrate support 11 on which the edge ring 112 is formed (for example, by thermal spraying) is disposed inside the plasma processing apparatus 1.

Next, in step S3, the control device 2 loads the substrate W into the plasma processing chamber 10, places the substrate W on the substrate support 11, supplies a desired gas from the gas supply 20, generates plasma by supplying the RF power from the power supply 30, and performs a desired plasma processing on the substrate W.

Next, in step S4, the control device 2 detects the wear of the edge ring 112. As an example of a method for detecting the wear of the edge ring 112, correlation information between an RF power usage time and an extent of wear (thickness) of the edge ring 112 may be measured in advance, and the correlated information may be stored in the storage device 2a2. Accordingly, the control device 2 can detect the extent of wear of the edge ring 112 from the RF power usage time.

As another example of the method for detecting the wear of the edge ring 112, a sample substrate for detection may be prepared in advance by plasma processing, and the wear of the edge ring 112 may be detected using the sample substrate for detection. An edge shape of the sample substrate for detection subjected to a plasma etching process, for example, varies depending on the extent of wear of the edge ring 112. The extent of wear of the edge ring 112 can be detected according to a difference between the edge shape of the sample substrate for detection after the plasma etching process and an edge shape of a reference sample substrate subjected to the plasma etching process using an unworn edge ring 112.

Based on a result of detecting the wear of the edge ring 112 in step S4, the control device 2 in step S5 determines whether or not a correction is possible by applying the DC voltage to the electrode layer 113.

When the control device 2 determines in step S5 that the correction is possible, the control device 2 in step S6 controls the DC voltage applied to the electrode layer 113 and corrects the sheath thickness on the edge ring 112 according to the wear of the edge ring 112. Accordingly, an ion incident angle is adjusted to a vertical direction, and the process returns to step S3, thereby making it possible to perform the plasma processing on the substrate W while correcting the edge shape to be processed on the substrate W.

When the control device 2 determines in step S5 that the correction is not possible, the control device 2 in step S7 unloads the substrate support 11 from the plasma processing apparatus 1, and restores (recoats) the edge ring 112 by secondary film formation (for example, re-thermal spraying). During the recoating, the film formation (for example, thermal spraying) can be performed in an unworn state of the upper surface portion 112a and the outer side surface portion 112c of the edge ring 112. However, the film formation (for example, thermal spraying) on the step portion 112d and the inner side surface portion 112b of the edge ring 112 is difficult because the gap 1112 is narrow. Hence, it is preferable to perform the film formation (for example, thermal spraying) after removing the electrostatic chuck 1111 from the base 1110.

Returning to step S2, the restored edge ring 112 is repositioned inside the plasma processing apparatus 1, and the plasma processing of the substrate W in step S3 and subsequent processes are performed.

The wear correction method for the edge ring 112 described above includes the steps of detecting wear of the edge ring 112, determining whether or not correction is possible by applying a DC voltage to the electrode layer 113 based on the detection result, correcting the wear of the edge ring 112 by controlling the DC voltage to the electrode layer 113 when it is determined that the correction is possible, and restoring the edge ring 112 by secondary film formation (for example, re-thermal spraying) when it is determined that the correction is not possible.

According to the edge ring 112 described above, it is possible to provide the edge ring 112 having a reduced thermal resistance and a good thermal conductivity. In addition, the wear correction method according to the wear of the edge ring 112 may improve the edge shape of the substrate, and further extend a service life of the edge ring 112.

According to one aspect of the present disclosure, it is possible to provide a plasma processing apparatus having an edge ring with reduced thermal resistance and improved thermal conductivity, a substrate support, and a method for correcting wear of the edge ring.

For example, the substrate processing apparatus to which the contents of the present disclosure are applied may be a substrate processing apparatus other than the plasma processing apparatus 1.

In addition, the edge ring 112 may be formed by any method other than thermal spraying, as long as the edge ring has a film structure. For example, the edge ring may be formed by CVD, PVD, sol gel, or additive manufacturing technology (3D printing technology), for example.

Various aspects of the subject-matter described herein may be set out non-exhaustively in the following numbered clauses:

### (Clause 1)

A plasma processing apparatus comprising:
a plasma processing chamber;
a base disposed inside the plasma processing chamber, and including a first part having an upper surface on which an electrostatic chuck is disposed, and a second part surrounding a periphery of the first part and having an upper surface higher than the first part; and
an edge ring formed by film formation on the upper surface of the second part and on a portion of side surfaces of the second part.

### (Clause 2)

The plasma processing apparatus according to Clause 1, wherein the portion of the side surfaces of the second part is a portion of an inner side surface and an outer side surface of the second part continuous with the upper surface of the second part.

### (Clause 3)

The plasma processing apparatus according to Clause 2, wherein the side surfaces of the edge ring are formed by film formation to any height between a step portion formed on the inner side surface of the second part and a bottom portion of the second part.

### (Clause 4)

The plasma processing apparatus according to any one of Clauses 1 to 3, wherein the upper surface of the second part and a portion of the side surfaces of the second part are surfaces exposed to plasma.

### (Clause 5)

The plasma processing apparatus according to any one of Clauses 1 to 4, wherein the edge ring is formed of identical film forming materials on the upper surface of the second part and on the side surfaces of the second part.

### (Clause 6)

The plasma processing apparatus according to any one of Clauses 1 to 4, wherein the edge ring is formed of different film forming materials on the upper surface of the second part and on the side surfaces of the second part.

### (Clause 7)

The plasma processing apparatus according to any one of Clauses 1 to 6, wherein the edge ring is formed on the upper surface of the second part via an electrode layer embedded in a first insulator.

### (Clause 8)

The plasma processing apparatus according to Clause 7, wherein a power supply terminal penetrating the second part and the electrode layer are coupled.

### (Clause 9)

The plasma processing apparatus according to Clause 8, wherein:
an insulator is disposed in a through hole of the second part, and
a power supply terminal penetrating the insulator and the electrode layer are coupled.

### (Clause 10)

The plasma processing apparatus according to Clause 7, wherein a power supply electrode film, embedded in a second insulator, is provided on the outer side surface of the second part by film formation, and the power supply electrode film is coupled to the electrode layer.

### (Clause 11)

The plasma processing apparatus according to Clause 10, wherein the power supply electrode film is formed along a thickness direction from the upper surface to a lower surface of the second part, and is provided at a plurality of locations along a circumferential direction.

### (Clause 12)

The plasma processing apparatus according to Clause 7, wherein the electrode layer is formed in an annular shape in a circumferential direction by film formation.

### (Clause 13)

The plasma processing apparatus according to Clause 10, wherein the first insulator and the second insulator are formed by film formation.

### (Clause 14)

The plasma processing apparatus according to any one of Clauses 1 to 13, wherein a flow path formed in the first part and a flow path formed in the second part are integrated.

### (Clause 15)

The plasma processing apparatus according to any one of Clauses 1 to 13, wherein a flow path formed in the first part and a flow path formed in the second part are separate entities.

### (Clause 16)

The plasma processing apparatus according to any one of Clauses 1 to 15, further comprising:
the electrostatic chuck disposed on the upper surface of the first part.

### (Clause 17)

A substrate support comprising:
a base including a first part having an upper surface on which an electrostatic chuck is disposed, and a second part surrounding a periphery of the first part and having an upper surface higher than the first part; and
an edge ring formed by film formation on the upper surface of the second part and on a portion of side surfaces of the second part.

### (Clause 18)

A method for correcting wear of an edge ring using a plasma processing apparatus including:
a plasma processing chamber;
a base disposed inside the plasma processing chamber, and including a first part having an upper surface on which an electrostatic chuck is disposed, and a second part surrounding a periphery of the first part and having an upper surface higher than the first part; and
an edge ring formed by film formation on the upper surface of the second part and on a portion of side surfaces of the second part, wherein the edge ring is formed on the upper surface of the second part via an electrode layer embedded in a first insulator,
the method for correcting the wear of the edge ring comprising:
detecting the wear of the edge ring;
determining whether or not the wear of the edge ring can be corrected by applying a DC voltage to the electrode layer based on a result of the detecting;
correcting the wear of the edge ring by adjusting the DC voltage applied to the electrode layer in a case where the determining determines that the edge ring can be corrected; and
restoring the edge ring by secondary film formation in a case where the determining determines that the edge ring cannot be corrected.

Although the embodiments are numbered with, for example, “first,” or “second,” the ordinal numbers do not imply priorities of the embodiments. Many other variations and modifications will be apparent to those skilled in the art.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. In addition, constituent elements in different embodiments may be combined to form other embodiments. The accompanying claims and their equivalents are intended to cover such forms or modifications as would fall within the scope and spirit of the disclosures.

For example, in the embodiments described above, the capacitively coupled plasma apparatus is described as an example, but the present disclosure is not limited thereto, and may be applied to other plasma apparatuses. For example, an inductively coupled plasma (ICP) apparatus may be used in place of the capacitively coupled plasma apparatus. In this case, the inductively coupled plasma device includes an antenna and a lower electrode. The lower electrode is disposed inside the substrate support, and the antenna is disposed in an upper portion of the chamber or is disposed above the chamber. Further, an RF generator is coupled to the antenna, and a DC generator is coupled to the lower electrode. Accordingly, the RF generator is coupled to the upper electrode of the capacitively coupled plasma apparatus or to the antenna of the inductively coupled plasma apparatus. That is, the RF generator is coupled to the plasma processing chamber 10.

What is claimed is:

1. A plasma processing apparatus comprising:
a plasma processing chamber;
a base disposed inside the plasma processing chamber, and including a first part having an upper surface on which an electrostatic chuck is disposed, and a second part surrounding a periphery of the first part and having an upper surface higher than the first part; and
an edge ring formed by film formation on the upper surface of the second part and on a portion of side surfaces of the second part.

2. The plasma processing apparatus as claimed in claim 1, wherein the portion of the side surfaces of the second part is a portion of an inner side surface and an outer side surface of the second part continuous with the upper surface of the second part.

3. The plasma processing apparatus as claimed in claim 2, wherein the side surfaces of the edge ring are formed by film formation to any height between a step portion formed on the inner side surface of the second part and a bottom portion of the second part.

4. The plasma processing apparatus as claimed in claim 1, wherein the upper surface of the second part and a portion of the side surfaces of the second part are surfaces exposed to plasma.

5. The plasma processing apparatus as claimed in claim 1, wherein the edge ring is formed of identical film forming materials on the upper surface of the second part and on the side surfaces of the second part.

6. The plasma processing apparatus as claimed in claim 1, wherein the edge ring is formed of different film forming materials on the upper surface of the second part and on the side surfaces of the second part.

7. The plasma processing apparatus as claimed in claim 1, wherein the edge ring is formed on the upper surface of the second part via an electrode layer embedded in a first insulator.

8. The plasma processing apparatus as claimed in claim 7, wherein a power supply terminal penetrating the second part and the electrode layer are coupled.

9. The plasma processing apparatus as claimed in claim 8, wherein:
an insulator is disposed in a through hole of the second part, and
a power supply terminal penetrating the insulator and the electrode layer are coupled.

10. The plasma processing apparatus as claimed in claim 7, wherein a power supply electrode film, embedded in a second insulator, is provided on the outer side surface of the second part by film formation, and the power supply electrode film is coupled to the electrode layer.

11. The plasma processing apparatus as claimed in claim 10, wherein the power supply electrode film is formed along a thickness direction from the upper surface to a lower surface of the second part, and is provided at a plurality of locations along a circumferential direction.

12. The plasma processing apparatus as claimed in claim 7, wherein the electrode layer is formed in an annular shape in a circumferential direction by film formation.

13. The plasma processing apparatus as claimed in claim 10, wherein the first insulator and the second insulator are formed by film formation.

14. The plasma processing apparatus as claimed in claim 1, wherein a flow path formed in the first part and a flow path formed in the second part are integrated.

15. The plasma processing apparatus as claimed in claim 1, wherein a flow path formed in the first part and a flow path formed in the second part are separate entities.

16. The plasma processing apparatus as claimed in claim 1, further comprising:
the electrostatic chuck disposed on the upper surface of the first part.

17. A substrate support comprising:
a base including a first part having an upper surface on which an electrostatic chuck is disposed, and a second part surrounding a periphery of the first part and having an upper surface higher than the first part; and
an edge ring formed by film formation on the upper surface of the second part and on a portion of side surfaces of the second part.

18. A method for correcting wear of an edge ring using a plasma processing apparatus including:
a plasma processing chamber;
a base disposed inside the plasma processing chamber, and including a first part having an upper surface on which an electrostatic chuck is disposed, and a second part surrounding a periphery of the first part and having an upper surface higher than the first part; and
an edge ring formed by film formation on the upper surface of the second part and on a portion of side surfaces of the second part, wherein the edge ring is formed on the upper surface of the second part via an electrode layer embedded in a first insulator,
the method for correcting the wear of the edge ring comprising:
detecting the wear of the edge ring;
determining whether or not the wear of the edge ring can be corrected by applying a DC voltage to the electrode layer based on a result of the detecting;
correcting the wear of the edge ring by adjusting the DC voltage applied to the electrode layer in a case where the determining determines that the edge ring can be corrected; and
restoring the edge ring by secondary film formation in a case where the determining determines that the edge ring cannot be corrected.
